(19) United States
(12) Patent Application Publication
(10) Pub. No.: US 2025/0239539 A1
(43) Pub. Date: Jul. 24, 2025

(54) SEMICONDUCTOR DEVICE HAVING CAPACITOR ARCHITECTURE USING CHIPPING DETECTION CIRCUITS

(71) Applicant: Samsung Electronics Co., Ltd., Suwon-si (KR)

(72) Inventors: Minsu JEONG, Suwon-si (KR); Ahreum KIM, Suwon-si (KR); Ansoo PARK, Suwon-si (KR); Changyeon YU, Suwon-si (KR)

(73) Assignee: Samsung Electronics Co., Ltd., Suwon-si (KR)

(21) Appl. No.: 18/917,259

(22) Filed: Oct. 16, 2024

(30) Foreign Application Priority Data
Jan. 24, 2024 (KR) 10-2024-0010997

(51) Int. Cl. H01L 23/00; H01L 21/78; H01L 23/522; H10B 43/27; H10B 43/35; H10B 43/40

(52) U.S. Cl. CPC H01L 23/562; H01L 21/78; H01L 23/5223; H10B 43/27; H10B 43/35; H10B 43/40

(57) ABSTRACT

A semiconductor device having a capacitor architecture using chipping detection circuits. The semiconductor device includes a first chipping detection circuit and a second chipping detection circuit adjacent to each other in a chip edge region of the semiconductor device, having a same shape as each other, in which contacts and lines are stacked as multiple layers, and each including a line structure, an input buffer, and an output buffer connected to the line structure, and a control logic circuit configured to float the input buffers of the first and second chipping detection circuits. The control logic circuit configured to provide a first power voltage to the line structure of the first chipping detection circuit and a second power voltage to the line structure of the second chipping detection circuit.

### CROSS-REFERENCE TO RELATED APPLICATION

This application is based on and claims priority under 35 U.S.C. § 119 to Korean Patent Application No. 10-2024-0010997, filed on Jan. 24, 2024, in the Korean Intellectual Property Office, the disclosure of which is incorporated by reference herein in its entirety.

### BACKGROUND

The inventive concepts relate to semiconductor devices, and more particularly, to semiconductor devices having a capacitor architecture using chipping detection circuits.

An integrated circuit (IC) includes one or more semiconductor devices. As the sizes of the semiconductor devices have decreased, the sizes of circuit components of the semiconductor devices have decreased. As the semiconductor devices, for example, memory devices, have increased operating speeds, internal power voltage levels of the memory devices may fluctuate due to high-speed sensing switching. This fluctuation can be a main factor causing a sensing malfunction. Thus, from among the circuit components, capacitors are required in order to reduce the effects by the voltage fluctuation. As semiconductor devices have had reduced chip sizes, an area to arrange the capacitors may be limited.

In addition, a wafer on which a semiconductor fabrication is processed may undergo an electrical die sort (EDS) process and may then undergo a sawing process (sometimes referred to as a dicing process) in which a plurality of dies on the wafer are isolated into separate dies. When the wafer is cut by using a wafer cutting blade or by using laser in the sawing process, defects, such as cracks or chipping, may occur in the dies. Because dies including such defects of cracks or chipping are not able to operate as normal semiconductor devices, the dies including the defects such as cracks or chipping may have to be screened in a test operation. To this end, a semiconductor device may detect the cracks or chipping by forming a chipping detection circuit in a chip edge region.

As such, there has been research into providing a capacitor of the semiconductor device by using a chipping detection circuit determined to have no cracks or chipping.

### SUMMARY

The inventive concepts provide semiconductor devices having a capacitor architecture using chipping detection circuits. For example, it may be advantageous to reduce the effects by voltage fluctuation and improve the performance of the semiconductor device, which has a decreased area available for the capacitor

According to some aspects of the inventive concepts, there is provided a semiconductor device including a first chipping detection circuit and a second chipping detection circuit which are each configured to detect cracks of the semiconductor device, adjacent to each other in a chip edge region of the semiconductor device, have a same shape, in which contacts and lines are stacked as multiple layers, and comprises a line structure, an input buffer, and an output buffer connected to the line structure, the line structure comprising a line connected from a first conductive layer to a second conductive layer of the semiconductor device; and a control logic circuit configured to float the input buffer of the first chipping detection circuit by using a first switch, float the input buffer of the second chipping detection circuit by using a second switch, provide a first power voltage to the line structure of the first chipping detection circuit by using a first power switch, and provide a second power voltage to the line structure of the second chipping detection circuit by using a second power switch.

According to some aspects of the inventive concepts, there is provided a semiconductor device including a first chipping detection circuit and a second chipping detection circuit which are each configured to detect cracks of the semiconductor device, adjacent to each other in a chip edge region of the semiconductor device, have a same shape as each other, in which contacts and lines are stacked as multiple layers, and including a line structure, an input buffer, and an output buffer connected to the line structure, the line structure including a line connected from a plurality of conductive layers of the semiconductor device to a lowermost conductive layer of the semiconductor device, and a control logic circuit configured to float the input buffer of the first chipping detection circuit by using a first switch, float the input buffer of the second chipping detection circuit by using a second switch, isolate the line structure of the first chipping detection circuit into a first line and a second line by using a first isolation switch, and isolate the line structure of the second chipping detection circuit into a third line and a fourth line by using a second isolation switch, the control logic circuit being further configured to provide a first power voltage to the first line by using a first power switch, provide a second power voltage to the second line by using a second power switch, provide a third power voltage to the third line by using a third power switch, and provide a fourth power voltage to the fourth line by using a fourth power switch.

According to some aspects of the inventive concepts, there is provided a semiconductor device including a first chipping detection circuit and a second chipping detection circuit which are each configured to detect cracks of the semiconductor device, adjacent to each other in a chip edge region of the semiconductor device, and have a same shape as each other, including a line structure, an input buffer, and an output buffer connected to the line structure, the line structure including a line connected from a plurality of conductive layers of the semiconductor device to a lowermost conductive layer of the semiconductor device, and a control logic circuit configured to float the input buffer of the first chipping detection circuit by using a first switch and float the input buffer of the second chipping detection circuit by using a second switch, the control logic circuit further configured to control a first power switch to provide a first power voltage, control a second power switch to provide a second power voltage, and control a third power switch to provide a third power voltage, the first and second power switches being connected to the line structure of the first chipping detection circuit, and the third power switch being connected to the line structure of the second chipping detection circuit.

### BRIEF DESCRIPTION OF THE DRAWINGS

Example embodiments will be more clearly understood from the following detailed description taken in conjunction with the accompanying drawings in which:

FIG. 1 is a view to describe a sawing process of a semiconductor wafer, according to some example embodiments;

FIG. 2 is a view of a semiconductor device according to some example embodiments;

FIG. 3 is a view of a portion of first and second chipping detection circuits of FIG. 2;

FIG. 4 is a view of chipping detection circuits according to some example embodiments;

FIGS. 5A, 5B, and 5C are views of a line structure of the chipping detection circuits of FIG. 4;

FIGS. 6 and 7 are views of chipping detection circuits according to some example embodiments;

FIGS. 8 and 9 are views of chipping detection circuits according to some example embodiments;

FIG. 10 is a view of a memory device according to some example embodiments;

FIG. 11 is a block diagram of an example in which a memory device is implemented in a solid-state drive (SSD) system, according to some example embodiments; and

FIG. 12 is a block diagram of a system of an electronic device including a memory device according to some example embodiments.

### DETAILED DESCRIPTION OF THE EMBODIMENTS

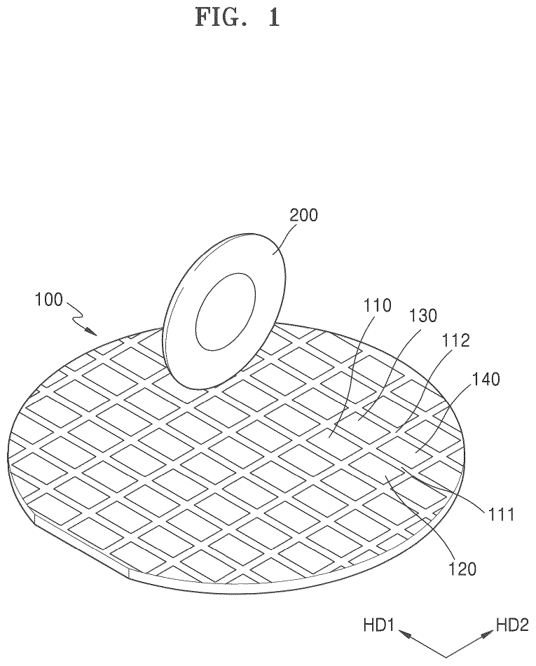

FIG. 1 is a view to describe a sawing process of a semiconductor wafer 100 according to some example embodiments.

Referring to FIG. 1, semiconductor chips 110, 120, 130, and 140 may be regularly and repetitively formed on the semiconductor wafer 100. Between the semiconductor chips 110 to 140, scribe lanes 111 and 112 may be formed in a first direction HD1 of the semiconductor wafer 100 and a second direction HD2, which is perpendicular to the first direction HD1. In the scribe lanes 111 and 112, various test process patterns, test pads connected to the test process patterns, and patterns for photo-lithography, such as overlay keys or alignment keys, may be formed. Also, redistribution pads, test circuits connected to the redistribution pads, and redistribution lines may be formed in the scribe lanes 111 and 112.

According to some example embodiments, the redistribution pads may be used for a semiconductor chip package, for example, a wafer level-chip scale package (WL-CSP). As the sizes of the semiconductor chips 110 to 140 have decreased, a fine pitch ball grid array (FBGA) package, a chip-scale package (CSP), a micro-ball grid array (pBGA) package, or a WL-CSP, which is small-sized and capable of realizing a plurality of pins, has been developed, from among semiconductor chip packages. The WL-CSP may use redistribution (or realignment) of a bonding pad of a semiconductor chip. The WL-CSP has a structural characteristic in which a bonding pad is directly redistributed above a semiconductor chip as another pad having a greater size than the bonding pad, and an external connection terminal, such as a solder ball or a bonding wire, is formed thereabove in a process of manufacturing a semiconductor device.

The semiconductor wafer 100 may be cut along the scribe lanes 111 and 112 to isolate the semiconductor chips 110 to 140 from one another. The cutting may be performed by using a cutter 200, for example, a diamond wheel blade. According to some example embodiments, the cutting may be performed by using laser sawing in which a laser beam is irradiated onto the semiconductor wafer 100 along the scribe lanes 111 and 112.

The thickness of the semiconductor wafer 100 has been decreased, and the sizes of the semiconductor chips 110 to 140 have been decreased. Accordingly, the number of test pads and the number of redistribution pads on the scribe lanes 111 and 112 have increased, and thus, the metal density in the scribe lanes 111 and 112 has increased. Thus, during the sawing of the semiconductor wafer 100, physical shocks, metal detachment of pads, particle contamination, or the like may occur to any one of the semiconductor chips 110 to 140, to cause defects, such as cracks or chipping, in the semiconductor chips 110 to 140. In order to screen a defective chip, the semiconductor chips 110 to 140 may include a chipping detection circuit. For convenience of explanation, the semiconductor chips 110 to 140 may be interchangeably referred to as semiconductor devices 110 to 140.

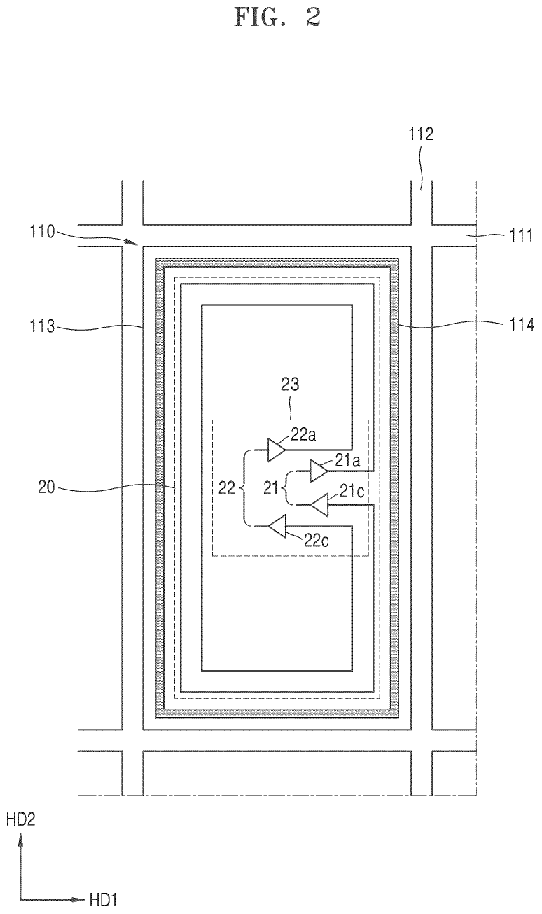

FIG. 2 is a view of a semiconductor device according to some example embodiments. FIG. 2 shows the semiconductor device 110 as a representative example from among the semiconductor devices 110 to 140 arranged on the semiconductor wafer 100 of FIG. 1. The description with respect to the semiconductor device 110 may be likewise applied to the other semiconductor devices 120 to 140. The semiconductor device 110 may inspect, by using a chipping detection circuit 20, whether cracks are generated in a chip, in a test mode.

Referring to FIG. 2, the semiconductor device 110 may include the chipping detection circuit 20 arranged to be adjacent to a chip edge 113. A crack prevention structure (sometimes referred to as a guard ring) 114 for preventing or reducing cracks which may occur when the semiconductor device 110 is separated from the wafer 100, may be formed between the chipping detection circuit 20 and the chip edge 113.

The chipping detection circuit 20 may include a first chipping detection circuit 21 and a second chipping detection circuit 22. The first chipping detection circuit 21 may include an input buffer 21a, a line structure 21b, and an output buffer 21c. The second chipping detection circuit 22 may include an input buffer 22a, a line structure 22b, and an output buffer 22c. The line structure 21b of the first chipping detection circuit 21 and the line structure 22b of the second chipping detection circuit 22 may be arranged to be adjacent to each other. The line structures 21b and 22b of the first and second chipping detection circuits 21 and 22 may have the same or substantially the same shapes, in which contacts and lines are stacked as multiple layers.

According to some example embodiments, the first chipping detection circuit 21 may inspect cracks of the semiconductor device 110, based on a logic level of an input signal applied to the input buffer 21a and a logic level of an output signal output from the output buffer 21c in the test mode. The second chipping detection circuit 22 may inspect cracks of the semiconductor device 110, based on a logic level of an input signal applied to the input buffer 22a and a logic level of an output signal output from the output buffer 22c in the test mode. When cracks occur in the line structures 21b and 22b, some portions of the line structures 21b and 22b may be opened or the resistance of the line structures 21b and 22b may increase so that the logic level of the input signal may become different from the logic level of the output signal in each of the first and second chipping detection circuits 21 and 22. That is, each of the first and second chipping detection circuits 21 and 22 may compare the logic level of the input signal with the logic level of the output signal to inspect the cracks occurring in the semiconductor device 110.

When it is determined in the test mode that there are no cracks (for example, that no cracks are detected or present) in the semiconductor device 110, the line structures 21b and 22b of the first and second chipping detection circuits 21 and 22 may be designed to function as (a) power decoupling capacitor(s) in a normal mode of the semiconductor device 110. The power decoupling capacitor may be connected to a power line and may function as a buffer for a radical change of a power voltage. Here, the capacitor may operate as a type of low pass filter providing power noise, and it is desirable that the capacitor has an increased electrical capacitance. The capacitor may have a structure in which a dielectric is arranged between two conductors. An electrical capacitance of the capacitor may be proportional to an area of the conductor and inversely proportional to a distance between the conductors. In the semiconductor device 110 having a chip with a decreased size, an area of the capacitor may be decreased, but the decreased area of the capacitor may cause a decrease of the electrical capacitance. Thus, it may be difficult to obtain an electrical capacitance as required. By providing a plurality of capacitors by using the chipping detection circuit, the effects of noise due to power voltage fluctuation may be reduced and the performance of the semiconductor device may be improved.

Hereinafter, configurations of the first and second chipping detection circuits 21 and 22 are to be described in detail according to various embodiments.

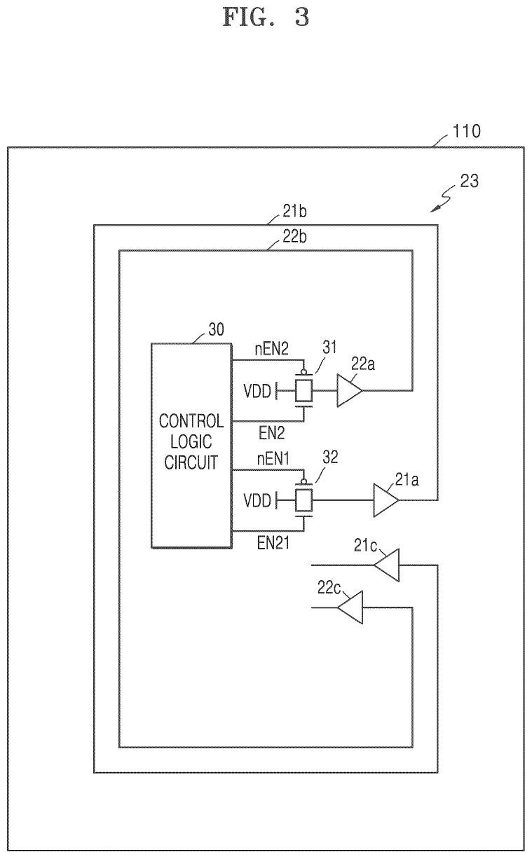

FIG. 3 is a view of a portion 23 of the first and second chipping detection circuits 21 and 22 of FIG. 2.

Referring to FIGS. 2 and 3, the input buffers 21a and 22a of the first and second chipping detection circuits 21 and 22 may be connected to first and second switches 31 and 32, respectively. The first and second switches 31 and 32 may include transmission gates. The first switch 31 may provide a level of a power voltage VDD to the input buffer 21a of the first chipping detection circuit 21 in response to first control signals EN1 and nEN1. The logic level of the first control signal EN1 may be opposite to the logic level of the complementary first control signal nEN1, and the first control signal EN1 may be connected to an n-type metal oxide semiconductor (NMOS) transistor of the transmission gate and the complementary first control signal nEN1 may be connected to a p-type metal oxide semiconductor (PMOS) transistor of the transmission gate. The second switch 32 may provide a level of a power voltage VDD to the input buffer 22a of the second chipping detection circuit 22 in response to second control signals EN2 and nEN2. The logic level of the second control signal EN2 may be opposite to the logic level of the complementary second control signal nEN2, and the second control signal EN2 may be connected to the NMOS transistor of the transmission gate and the complementary second control signal nEN2 may be connected to the PMOS transistor of the transmission gate.

The semiconductor device 110 may include a control logic circuit 30 configured to control operations of the semiconductor device 110. The control logic circuit 30 may provide control signals for controlling circuits of the semiconductor device 110. The control logic circuit 30 may control the first and second chipping detection circuits 21 and 22 to perform an operation of inspecting cracks by using the first control signals EN1 and nEN1 and the second control signals EN2 and nEN2. For example, the first control signal EN1 and the second control signal EN2 may be provided as logic high levels to turn on the first and second switches 31 and 32, and thus, the first and second chipping detection circuits 21 and 22 may inspect the cracks of the semiconductor device 110 based on the level of the power voltage VDD input as input signals.

According to some example embodiments, an example in which the level of the power voltage VDD is provided as the input signals of the first and second chipping detection circuits 21 and 22 is described. However, it is only an example for helping understand the inventive concepts and does not limit the inventive concepts. According to some example embodiments, a level of a ground voltage VSS may be provided as the input signals of the first and second chipping detection circuits 21 and 22. According to some example embodiments, different input signals may be provided to the first and second chipping detection circuits 21 and 22. For example, the level of the power voltage VDD may be provided as the input signal of the first chipping detection circuit 21 and the level of the ground voltage VSS may be provided as the input signal of the second chipping detection circuit 22.

The control logic circuit 30 may control the line structures 21b and 22b of the first and second chipping detection circuits 21 and 22 to function as capacitors by using the first control signals EN1 and nEN1 and the second control signals EN2 and nEN2. For example, the first control signal EN1 and the second control signal EN2 may be provided as logic low levels to turn off the first and second switches 31 and 32, and thus, the first and second chipping detection circuits 21 and 22 may be in floating states. When the first and second chipping detection circuits 21 and 22 are in the floating states, the line structures 21b and 22b of the first and second chipping detection circuits 21 and 22 may operate as two conductors of the capacitors.

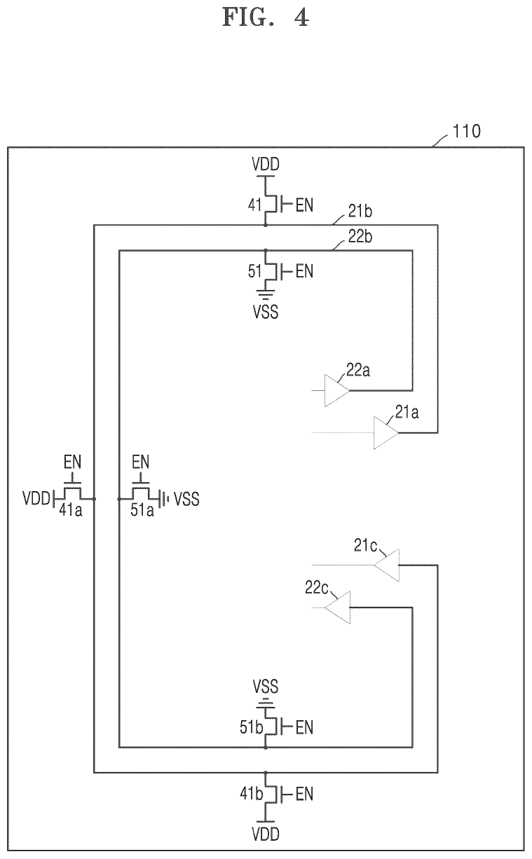

The first and second switches 31 and 32 may be controlled by the control logic circuit 30 and may support the first and second chipping detection circuits 21 and 22 to operate as the capacitors. FIG. 3 illustrates that the first and second switches 31 and 32 are separate components from the control logic circuit 30. However, the first and second switches 31 and 32 may be integral components of the control logic circuit 30. Hereinafter, various switches (for example, 41 and 51 of FIG. 4) illustrated as supporting the first and second chipping detection circuits 21 and 22 to function as the capacitors, may be realized as integral components of the control logic circuit 30.

FIG. 4 is a view of chipping detection circuits according to some example embodiments. Hereinafter, to simplify a circuit connection relationship, components in a floating state are indicated in a light color, as they are not connected.

Referring to FIGS. 2, 3, and 4, the line structure 21b of the first chipping detection circuit 21 may be connected to a first power switch 41 and the line structure 22b of the second chipping detection circuit 22 may be connected to a second power switch 51. The first and second power switches 41 and 51 may be formed as NMOS transistors. The first power switch 41 may provide a level of a power voltage VDD to the line structure 21b of the first chipping detection circuit 21 in response to a control signal EN. The second power switch 51 may provide a level of a ground voltage VSS to the line structure 22b of the second chipping detection circuit 22 in response to a control signal EN. When the control signal EN is provided as a logic high level, the first and second power switches 41 and 51 may be turned on, and the level of the power voltage VDD may be provided to the line structure 21b of the first chipping detection circuit 21 and the level of the ground voltage VSS may be provided to the line structure 22b of the second chipping detection circuit 22. Thus, the line structures 21b and 22b of the first and second chipping detection circuits 21 and 22 may operate as a power decoupling capacitor.

According to some example embodiments, the example in which the level of the power voltage VDD may be provided to the line structure 21b of the first chipping detection circuit 21 and the level of the ground voltage VSS may be provided to the line structure 22b of the second chipping detection circuit 22 is described. However, it is only for helping understand the inventive concepts and is not intended to limit the inventive concepts. According to some example embodiments, the level of the ground voltage VSS may be provided to the line structure 21b of the first chipping detection circuit 21 and the level of the power voltage VDD may be provided to the line structure 22b of the second chipping detection circuit 22.

According to some example embodiments, in order to increase the efficiency of the power decoupling capacitor including the line structures 21b and 22b of the first and second chipping detection circuits 21 and 22, a plurality of first power switches 41a and 41b may further be arranged in the line structure 21b of the first chipping detection circuit 21 and a plurality of second power switches 51a and 51b may further be arranged in the line structure 22b of the second chipping detection circuit 22.

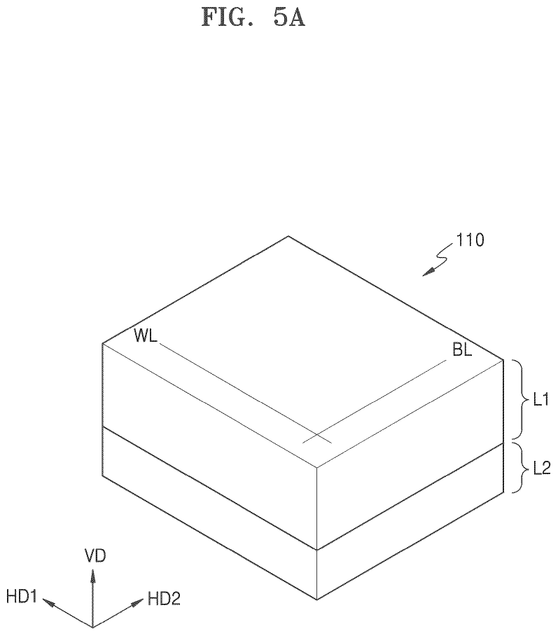

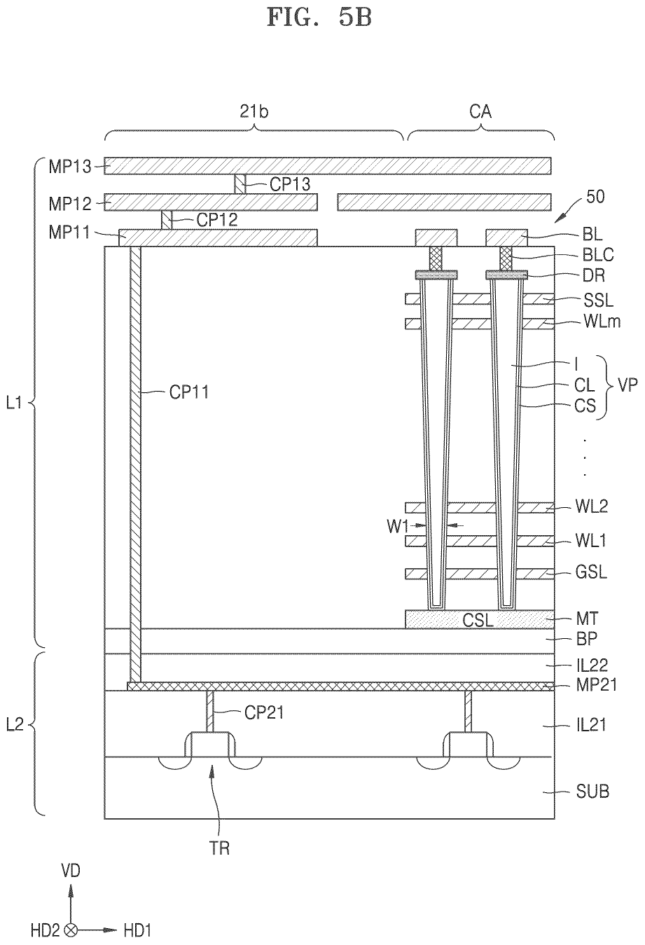

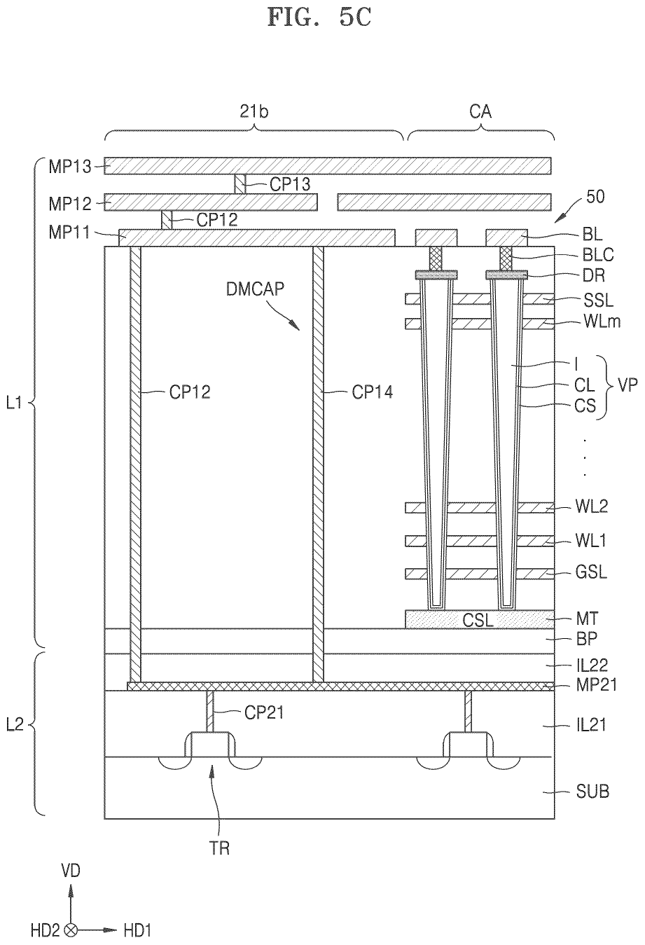

FIGS. 5A, 5B, and 5C are views of a line structure of the chipping detection circuits of FIG. 4.

Referring to FIGS. 4, 5A, and 5B, the semiconductor device 110 may be a memory device including a first semiconductor layer L1 and a second semiconductor layer L2. For convenience of explanation, the semiconductor device 110 may be referred to as a memory device, and the term semiconductor device may be interchangeably used with the term memory device, or may sometimes be referred to as nonvolatile memory device). The first semiconductor layer L1 may be stacked in a vertical direction VD with respect to the second semiconductor layer L2. In detail, the second semiconductor layer L2 may be arranged below the first semiconductor layer L1 in the vertical direction VD. The memory device 110 may have a cell over periphery (COP) structure including a cell array structure and a peripheral circuit structure overlapping each other in a vertical direction. The COP structure may effectively reduce an area in a horizontal direction and may improve the degree of integration of the memory device 110.

The memory device 110 may include a memory cell array 50, a row decoder, a page buffer, a control logic circuit, and a voltage generating circuit. The row decoder, the page buffer, the control logic circuit, and the voltage generating circuit (not shown) may be included in peripheral circuits. The memory cell array 50 may be formed on the first semiconductor layer L1, and the peripheral circuits may be formed on the second semiconductor layer L2. Accordingly, the memory device 110 may have a structure in which the memory cell array 50 is arranged above the peripheral circuits, that is, the COP structure.

According to some example embodiments, the second semiconductor layer L2 may include a substrate. Also, semiconductor devices, such as transistors, and patterns for interconnecting the devices may be formed on the substrate, to form the peripheral circuits on the second semiconductor layer L2. After the circuits are formed on the second semiconductor layer L2, the memory cell array 50 may be formed on the first semiconductor layer L1.

The memory cell array 50 may be arranged in a cell area CA and may include a plurality of word lines WL1 to WLm. The plurality of word lines WL1 to WLm may be stacked in the vertical direction VD and may extend in the first horizontal direction HD1. Although not shown, the plurality of word lines WL1 to WLm may be electrically insulated from each other by a plurality of insulating layers. Ends of the plurality of word lines WL1 to WLm in the first horizontal direction HD1 may be realized to have a stair shape. The memory cell array 50 may further include a common source line CSL arranged below the plurality of word lines WL1 to WLm.

The memory cell array 50 may further include a vertical channel structure VP (sometimes referred to as a vertical pillar). The vertical channel structure VP may extend in the vertical direction VD and may pass through the plurality of word lines WL1 to WLm and the plurality of insulating layers. The vertical channel structure VP may have a first width W1 in the first horizontal direction HD. For example, the plurality of vertical channel structures VP may be formed to have an annular shape. Here, the first width W1 may correspond to the size of a first channel hole. This is only an example for helping understand the inventive concepts and is not intended to limit the inventive concepts. Alternatively, the vertical channel structure VP may be formed to have an elliptic cylindrical shape or a rectangular cylindrical shape. The plurality of vertical channel structures VP may be arranged to be apart from each other in the first horizontal direction HD1 and the second horizontal direction HD2. The vertical channel structure VP may include a charge storage layer CS, a channel layer CL, and an internal layer I. The channel layer CL may include a silicon material of a first type (for example, a P type) and may function as a channel area. The internal layer I may include an insulating material such as silicon oxide or an air gap (for example, an open space defined by the channel layer CL occupied by air, such as atmospheric air, or a selected gas, or vacuum). The charge storage layer CS may include a gate insulating layer (sometimes referred to as a tunneling insulating layer), a charge trap layer, and a blocking insulating layer. For example, the charge storage layer CS may have an oxide-nitride-oxide (ONO) structure.

Drains or drain contacts DR may be provided on the plurality of vertical channel structures VP, respectively. For example, the drains or the drain contacts DR may include a silicon material doped with impurities of a second conductivity type (for example, an N type). Bit lines BL may be provided above the drain contacts DR, and the bit lines BL may be connected to the drain contacts DR, respectively, through bit line contacts BLC.

The memory cell array 50 may further include a ground selection line GSL between the plurality of word lines WL1 to WLm and the common source line CSL and a string selection line SSL arranged above the plurality of word lines WL1 to WLm. FIG. 5B illustrates that the memory device 110 may include one string selection line SSL. However, the inventive concepts are not limited thereto. According to some example embodiments, the memory device 110 may include two string selection lines stacked in the vertical direction VD.

The second semiconductor layer L2 may include a substrate SUB, a first lower insulating layer IL21, and a second lower insulating layer IL22. The substrate SUB may include a semiconductor substrate including a semiconductor material such as monocrystalline silicon or monocrystalline germanium and may be manufactured from a silicon wafer. The first and second lower insulating layers IL21 and IL22 may be formed by chemical vapor deposition (CVD), spin coating, etc. by using an insulating material such as silicon oxide. A plurality of semiconductor devices including a transistor TR may be formed on the substrate SUB included in the second semiconductor layer L2, and a gate line of the transistor TR may be electrically connected to a metal pattern MP21 formed on the second lower insulating layer IL22 through a contact CP21 passing through the first lower insulating layer IL21. The gate line of the transistor TR may extend in the first horizontal direction HD1 and may be referred to as the lowermost conductive layer of the semiconductor device 110.

The first semiconductor layer L1 may be stacked on the second semiconductor layer L2, and the first semiconductor layer L1 may include a base layer BP and an upper insulating layer IL1. According to some example embodiments, the base layer BP may be formed by sputtering, CVD, atomic layer deposition (ALD), physical vapor deposition (PVD), etc. by using polysilicon. According to some example embodiments, the base layer BP may be formed by forming an amorphous silicon layer on the second lower insulating layer IL22 and then changing the amorphous silicon layer into a monocrystalline silicon layer through heat processing or laser beam irradiation. Thus, defects in the base layer BP may be removed. According to some example embodiments, the base layer BP may be formed by a wafer bonding process. In this case, for example, a monocrystalline silicon wafer, may be bonded on the second lower insulating layer IL22, and then, an upper portion of the monocrystalline silicon wafer may be partially removed or planarized to form the base layer BP.

A first metal layer MP11 may be formed on the same or substantially the same level as the bit line BL of the first semiconductor layer L1, and a second metal layer MP12 and a third metal layer MP13 may be formed on the first metal layer MP11. An interlayer insulating layer may be formed between the first metal layer MP11 and the second metal layer MP12 and between the second metal layer MP12 and the third metal layer MP13. The first metal layer MP11 may be connected to the gate line of the transistor TR through a contact CP11, the first metal layer MP11 and the second metal layer MP12 may be connected to each other through a contact CP12, and the second metal layer MP12 and the third metal layer MP13 may be connected to each other through a contact CP13. According to some example embodiments, the third metal layer MP13 is shown as the uppermost conductive layer. However, this is only for helping understand the inventive concepts and is not intended to limit the inventive concepts.

According to some example embodiments, a line having a chain structure connected from the third metal layer MP13 of the first semiconductor layer L1, which is the uppermost conductive layer of the semiconductor device 110, to the gate line of the transistor TR of the second semiconductor layer L2, which is the lowermost conductive layer of the semiconductor device 110, through the contacts CP11 to CP13 and the first to third metal layers MP11 to MP13, may be included in the line structure 21b of the first chipping detection circuit 21. The line structure 21b of the first chipping detection circuit 21 may have the same or substantially the same shape as the line structure 22b of the second chipping detection circuit 22 arranged to be adjacent to the first chipping detection circuit 21. Thus, the line structures 21b and 22b of the first and second chipping detection circuits 21 and 22 may operate as a power decoupling capacitor of a power voltage VDD.

Referring to FIG. 5C, in order to increase the electrical capacitance of the power decoupling capacitor including the line structures 21b and 22b of the first and second chipping detection circuits 21 and 22, a dummy capacitor DMCAP may be formed. The line structure 21b of the first chipping detection circuit 21 may further include a line connected from the first metal layer MP11 of the first semiconductor layer L1 to the metal pattern MP21 of the second semiconductor layer L2 through a contact CP14. The line structure 21b of the first chipping detection circuit 21 may have the same or substantially the same shape as the line structure 22b of the second chipping detection circuit 22 arranged to be adjacent to the first chipping detection circuit 21, and thus, the electrical capacitance of the power decoupling capacitor including the line structures 21b and 22b of the first and second chipping detection circuits 21 and 22 may be increased by the dummy capacitor DMCAP.

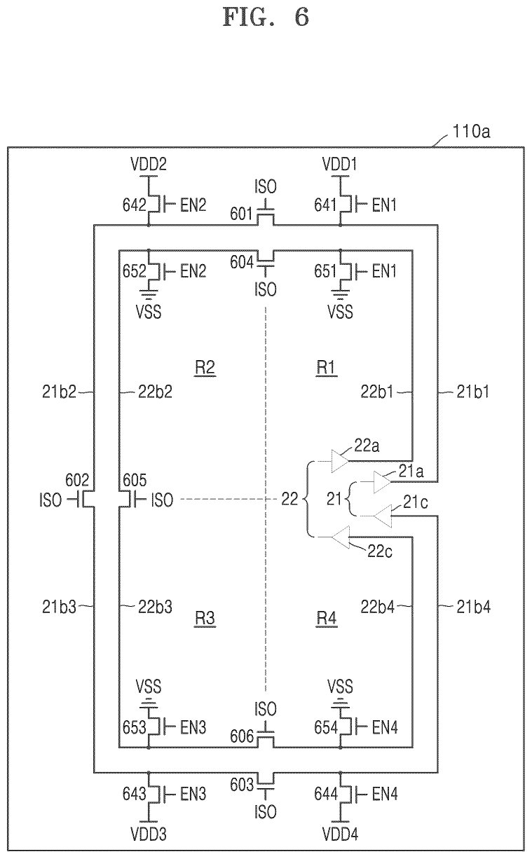

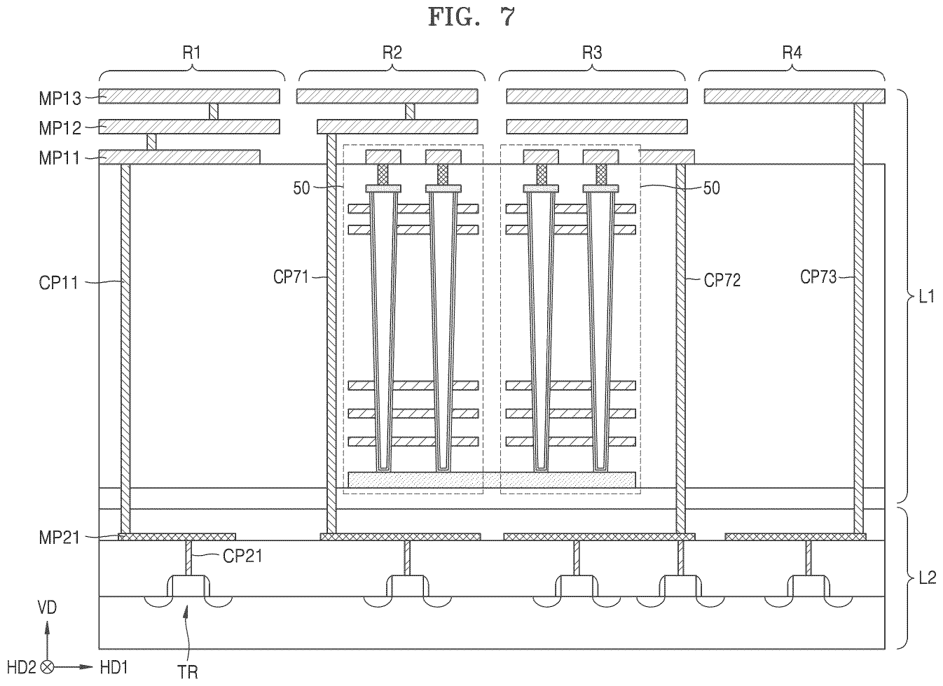

FIGS. 6 and 7 are views of chipping detection circuits according to some example embodiments. FIG. 7 is a view of line structures of the chipping detection circuit of FIG. 6. Hereinafter, subscripts attached to the same reference numeral in different drawings (for example, a of 110a and b of 110b) are used to distinguish a plurality of components having substantially the same or same functions from one another.

Referring to FIG. 6, in a memory device 110b, the first chipping detection circuit 21 may include a plurality of isolation switches 601, 602, and 603 controlled by an isolation control signal ISO. When the plurality of isolation switches 601 to 603 are turned off, the line structure 21b of the first chipping detection circuit 21 may be isolated into a plurality of line structures, namely, first to fourth line structures 21b1, 21b2, 21b3, and 21b4. When the plurality of isolation switches 601 to 603 are turned on, the plurality of line structures 21b1 to 21b4 of the first chipping detection circuit 21 may be connected to one another to form one line structure 21b.

The second chipping detection circuit 22 may include a plurality of isolation switches 604, 605, and 606 controlled by an isolation control signal ISO. When the plurality of isolation switches 604 to 606 are turned off, the line structure 22b of the second chipping detection circuit 22 may be isolated into a plurality of line structures, namely, first to fourth line structures 22b1, 22b2, 22b3, and 22b4. When the plurality of isolation switches 604 to 606 are turned on, the plurality of line structures 22b1 to 22b4 of the second chipping detection circuit 22 may be connected to one another to form one line structure 22b.

According to some example embodiments, the isolation switches 601 to 606 may include NMOS transistors and the isolation control signal ISO may be provided by the control logic circuit 30. When the isolation control signal ISO has a logic low level, the isolation switches 601 to 606 may be turned off, and when the isolation control signal ISO has a logic high level, the isolation switches 601 to 606 may be turned on. This is only for helping understand the inventive concepts, and it may be denoted that the line structures 21b and 22b of the first and second chipping detection circuits 21 and 22 may be isolated into the plurality of line structures 21b1 to 21b4 and 22b1 to 22b4, respectively, by the isolation switches 601 to 603 and 604 to 606, respectively.

The first line structure 21b1 of the first chipping detection circuit 21 may be connected to a first power switch 641, and the first line structure 22b1 of the second chipping detection circuit 22 may be connected to a second power switch 651. The first and second power switches 641 and 651 may include NMOS transistors. The first power switch 641 may provide a level of a first power voltage VDD1 to the first line structure 21b1 of the first chipping detection circuit 21 in response to a first control signal EN1. The second power switch 651 may provide a level of a ground voltage VSS to the first line structure 22b1 of the second chipping detection circuit 22 in response to a first control signal EN1. When the first control signal EN1 is provided as a logic high level, the first and second power switches 641 and 651 may be turned on and the level of the power voltage VDD may be provided to the first line structure 21b1 of the first chipping detection circuit 21 and the level of the ground voltage VSS may be provided to the first line structure 22b1 of the second chipping detection circuit 22. Thus, the first line structures 21b1 and 22b1 of the first and second chipping detection circuits 21 and 22 may operate as a power decoupling capacitor of the first power voltage VDD1.

The second line structure 21b2 of the first chipping detection circuit 21 may be connected to a first power switch 642, and the second line structure 22b2 of the second chipping detection circuit 22 may be connected to a second power switch 652. The first and second power switches 642 and 652 may include NMOS transistors. The first power switch 642 may provide a level of a second power voltage VDD2 to the second line structure 21b2 of the first chipping detection circuit 21 in response to a second control signal EN2. The second power switch 652 may provide a level of a ground voltage VSS to the second line structure 22b2 of the second chipping detection circuit 22 in response to a second control signal EN2. When the second control signal EN2 is provided as a logic high level, the first and second power switches 642 and 652 may be turned on and the level of the second power voltage VDD2 may be provided to the second line structure 21b2 of the first chipping detection circuit 21 and the level of the ground voltage VSS may be provided to the second line structure 22b2 of the second chipping detection circuit 22. Thus, the second line structures 21b2 and 22b2 of the first and second chipping detection circuits 21 and 22 may operate as a power decoupling capacitor of the second power voltage VDD2.

The third line structure 21b3 of the first chipping detection circuit 21 may be connected to a first power switch 643, and the third line structure 22b3 of the second chipping detection circuit 22 may be connected to a second power switch 653. The first and second power switches 643 and 653 may include NMOS transistors. The first power switch 643 may provide a level of a third power voltage VDD3 to the third line structure 21b3 of the first chipping detection circuit 21 in response to a third control signal EN3. The second power switch 653 may provide a level of a ground voltage VSS to the third line structure 22b3 of the second chipping detection circuit 22 in response to a third control signal EN3. When the third control signal EN3 is provided as a logic high level, the first and second power switches 643 and 653 may be turned on and the level of the third power voltage VDD3 may be provided to the third line structure 21b3 of the first chipping detection circuit 21 and the level of the ground voltage VSS may be provided to the third line structure 22b3 of the second chipping detection circuit 22. Thus, the third line structures 21b3 and 22b3 of the first and second chipping detection circuits 21 and 22 may operate as a power decoupling capacitor of the third power voltage VDD3.

The fourth line structure 21b4 of the first chipping detection circuit 21 may be connected to a first power switch 644, and the fourth line structure 22b4 of the second chipping detection circuit 22 may be connected to a second power switch 654. The first and second power switches 644 and 654 may include NMOS transistors. The first power switch 644 may provide a level of a fourth power voltage VDD4 to the fourth line structure 21b4 of the first chipping detection circuit 21 in response to a fourth control signal EN4. The second power switch 654 may provide a level of a ground voltage VSS to the fourth line structure 22b4 of the second chipping detection circuit 22 in response to a fourth control signal EN4. When the fourth control signal EN4 is provided as a logic high level, the first and second power switches 644 and 654 may be turned on and the level of the fourth power voltage VDD4 may be provided to the fourth line structure 21b4 of the first chipping detection circuit 21 and the level of the ground voltage VSS may be provided to the fourth line structure 22b4 of the second chipping detection circuit 22. Thus, the fourth line structures 21b4 and 22b4 of the first and second chipping detection circuits 21 and 22 may operate as a power decoupling capacitor of the fourth power voltage VDD4.

In FIG. 6, the first line structures 21b1 and 22b1 of the first and second chipping detection circuits 21 and 22 may be formed in a first region R1 of a memory device 110a. The second line structures 21b2 and 22b of the first and second chipping detection circuits 21 and 22 may be formed in a second region R2 of the memory device 110a, the third line structures 21b3 and 22b3 of the first and second chipping detection circuits 21 and 22 may be formed in a third region R3 of the memory device 110a, and the fourth line structures 21b4 and 22b4 of the first and second chipping detection circuits 21 and 22 may be formed in a fourth region R4 of the memory device 110a.

Referring to FIG. 7, in the first to fourth regions R1 to R4 of the memory device 110a, different components may be formed. For example, the second and third regions R2 and R3 may include the memory cell array 50 described with reference to FIG. 5B and the first and fourth regions R1 and R4 may not include the memory cell array 50. This may denote that the first line structures 21b1 and 22b1, the second line structures 21b2 and 22b2, the third line structures 21b3 and 22b3, and the fourth line structures 21b4 and 22b4 of the first and second chipping detection circuits 21 and 22 may be formed as different patterns.

For example, the first line structures 21b1 and 22b1 of the first and second chipping detection circuits 21 and 22 in the first region R1 may have a structure connected from the third metal layer MP13 of the first semiconductor layer L1, which is the uppermost conductive layer of the semiconductor device 110, to the gate line of the transistor TR of the second semiconductor layer L2, which is the lowermost conductive layer of the semiconductor device 110, through the contacts CP11, CP12, CP13, and CP21 and the first to third metal layers MP11, MP12, and MP13.

The second line structures 21b2 and 22b2 of the first and second chipping detection circuits 21 and 22 in the second region R2 may have a structure connected from the third metal layer MP13 of the first semiconductor layer L1 to the gate line of the transistor TR of the second semiconductor layer L2 through the contacts CP13 and CP21 and a contact CP71, and the second and third metal layers MP12 and MP13. The contact CP71 may connect the second metal layer MP12 of the first semiconductor layer L1 to the metal pattern MP21 of the second semiconductor layer L2.

The third line structures 21b3 and 22b3 of the first and second chipping detection circuits 21 and 22 in the third region R3 may have a structure connected from the first metal layer MP11 of the first semiconductor layer L1 to the gate line of the transistor TR of the second semiconductor layer L2 through a contact CP72 and the contact CP21 and the first metal layer MP11. The contact CP72 may connect the first metal layer MP11 of the first semiconductor layer L1 to the metal pattern MP21 of the second semiconductor layer L2.

The fourth line structures 21b4 and 22b4 of the first and second chipping detection circuits 21 and 22 in the fourth region R4 may have a structure connected from the third metal layer MP13 of the first semiconductor layer L1 to the gate line of the transistor TR of the second semiconductor layer L2 through a contact CP73 and the contact CP21 and the third metal layer MP13. The contact CP73 may connect the third metal layer MP13 of the first semiconductor layer L1 to the metal pattern MP21 of the second semiconductor layer L2.

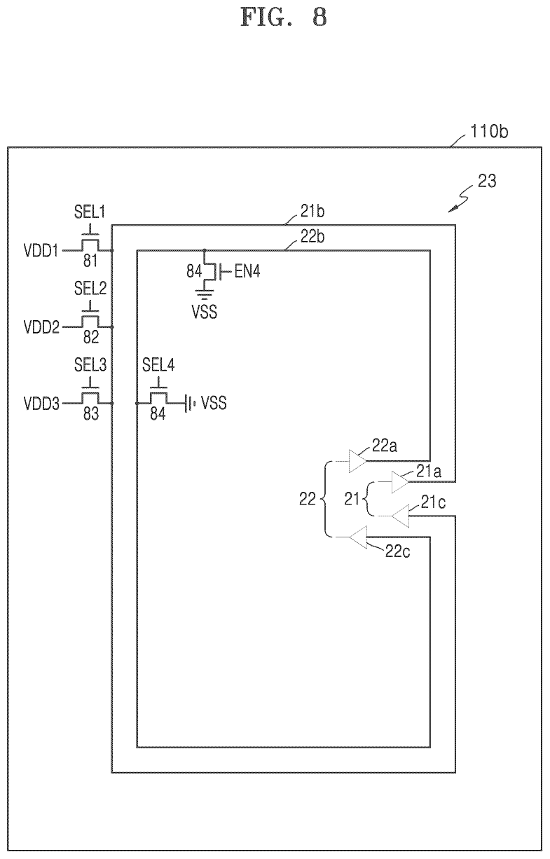

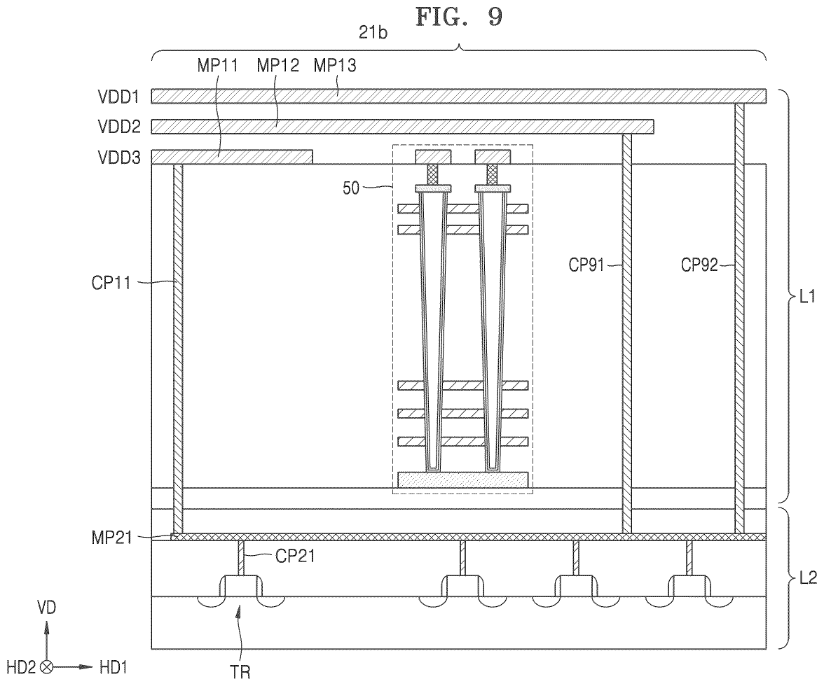

FIGS. 8 and 9 are views of chipping detection circuits according to some example embodiments. FIG. 9 is a view of line structures of the chipping detection circuit of FIG. 8.

Referring to FIG. 8, in the memory device 110b, the first and second chipping detection circuits 21 and 22 may include a plurality of power switches, namely, first to third power switches 81, 82, and 83, controlled by a plurality of selection control signals, namely, first to fourth selection control signals SEL1, SEL2, SEL3, and SEL4. The selection control signals SEL1 to SEL4 may be provided by the control logic circuit 30, and the power switches 81 to 83 may include NMOS transistors. The line structure 21b of the first chipping detection circuit 21 may be connected to the first power switch 81, the second power switch 82, and the third power switch 83.

The first power switch 81 may provide a level of a first power voltage VDD1 to the first line structure 21b of the first chipping detection circuit 21 in response to the first selection control signal SEL1. The second power switch 82 may provide a level of a second power voltage VDD2 to the line structure 21b of the first chipping detection circuit 21 in response to the second selection control signal SEL2. The third power switch 83 may provide a level of a third power voltage VDD3 to the line structure 21b of the first chipping detection circuit 21 in response to the third selection control signal SEL3. The fourth power switch 84 may provide a level of a ground voltage VSS to the line structure 22b of the second chipping detection circuit 22 in response to the fourth selection control signal SEL4.

According to some example embodiments, the control logic circuit 30 may control the first to third selection control signals SEL1 to SEL3 such that only one of the first to third power switches 81 to 83 may be turned on. The control logic circuit 30 may control the fourth selection control signal SEL4 such that the fourth power switch 84 may be simultaneously turned on when any one of the first to third power switches 81 to 83 is turned on. This is only for helping understand the inventive concepts, and it may be indicated that the line structures 21b and 22b of the first and second chipping detection circuits 21 and 22 may operate as a power-decoupling capacitor of the power voltage from among the first to third power voltages VDD1, VDD2, and VDD3 transmitted through the selected power switch.

Referring to FIG. 9, the third metal layer MP13 may be set as a line of the first power voltage VDD1, the second metal layer MP12 may be set as a line of the second power voltage VDD2, and the first metal layer MP11 may be set as a line of the first power voltage VDD1 in the first semiconductor layer L1. This is only an example for helping understand the inventive concepts and is not intended to limit the inventive concepts. According to some example embodiments, the third metal layer MP13 may be set as a line of the second power voltage VDD2, the second metal layer MP12 may be set as a line of the first power voltage VDD1, and the first metal layer MP11 may be changed to a line of the third power voltage VDD3.

The line structure 21b of the first chipping detection circuit 21 may be connected from the first metal layer MP11 of the first semiconductor layer L1 to the gate line of the transistor TR of the second semiconductor layer L2 through the contacts CP11 and CP21. The line structure 21b of the first chipping detection circuit 21 may be connected from the second metal layer MP12 of the first semiconductor layer L1 to the gate line of the transistor TR of the second semiconductor layer L2 through a contact CP91 and the contact CP21. The line structure 21b of the first chipping detection circuit 21 may be connected from the third metal layer MP13 of the first semiconductor layer L1 to the gate line of the transistor TR of the second semiconductor layer L2 through a contact CP92 and the contact CP21. The line structure 21b of the first chipping detection circuit 21 may have the same or substantially the same shape as the line structure 22b of the second chipping detection circuit 22 arranged to be adjacent to the first chipping detection circuit 21. Accordingly, the line structures 21b and 22b of the first and second chipping detection circuits 21 and 22 may operate as a power decoupling capacitor of a power voltage from among the first to third power voltages VDD1 to VDVD3 transmitted through the selected power switch.

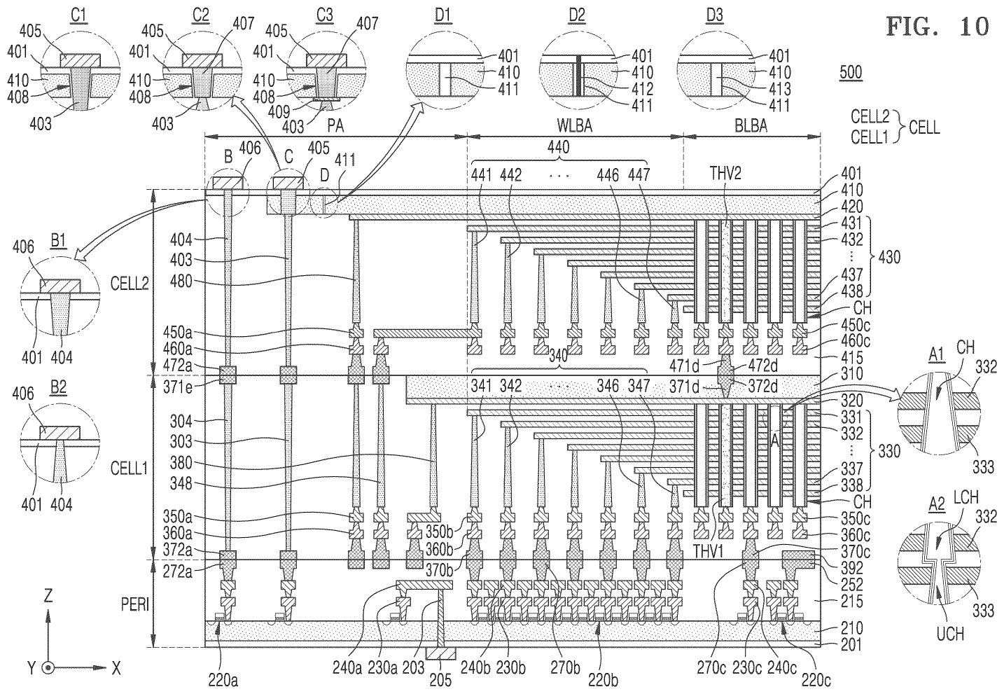

FIG. 10 is a view illustrating a memory device 500 according to some example embodiments.

Referring to FIG. 10, the memory device 500 may have a chip-to-chip (C2C) structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 500 may include the at least one upper chip including the cell region. For example, as illustrated in FIG. 10, the memory device 500 may include two upper chips. However, the number of upper chips is not limited thereto. In the case in which the memory device 500 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 10. However, example embodiments are not limited thereto. According to some example embodiments, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b and 220c formed on the first substrate 210. An interlayer insulating layer 215 including one or more insulating layers may be provided on the plurality of circuit elements 220a, 220b and 220c, and a plurality of metal lines electrically connected to the plurality of circuit elements 220a, 220b and 220c may be provided in the interlayer insulating layer 215. For example, the plurality of metal lines may include first metal lines 230a, 230b and 230c connected to the plurality of circuit elements 220a, 220b and 220c, and second metal lines 240a, 240b and 240c formed on the first metal lines 230a, 230b and 230c. The plurality of metal lines may be formed of at least one of various conductive materials. For example, the first metal lines 230a, 230b and 230c may be formed of tungsten having a relatively high electrical resistivity, and the second metal lines 240a, 240b and 240c may be formed of copper having a relatively low electrical resistivity.

The first metal lines 230a, 230b and 230c and the second metal lines 240a, 240b and 240c are illustrated and described in some example embodiments. However, example embodiments are not limited thereto. According to some example embodiments, at least one or more additional metal lines may further be formed on the second metal lines 240a, 240b and 240c. In this case, the second metal lines 240a, 240b and 240c may be formed of aluminum, and at least some of the additional metal lines formed on the second metal lines 240a, 240b and 240c may be formed of copper having an electrical resistivity lower than that of aluminum of the second metal lines 240a, 240b and 240c.

The interlayer insulating layer 215 may be disposed on the first substrate 210 and may include an insulating material such as silicon oxide and/or silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (for example, the Z-axis direction) perpendicular to a top surface of the second substrate 310. String selection lines and a ground selection line may be disposed on and under the word lines 330, and the plurality of word lines 330 may be disposed between the string selection lines and the ground selection line. Likewise, the second cell region CELL2 may include a third substrate 410 and a common source line 420, and a plurality of word lines 430 (431 to 438) may be stacked on the third substrate 410 in a direction (for example, the Z-axis direction) perpendicular to a top surface of the third substrate 410. Each of the second substrate 310 and the third substrate 410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

According to some example embodiments, as illustrated in a region ‘A1’, the channel structure CH may be provided in the bit line bonding region BLBA and may extend in the direction perpendicular to the top surface of the second substrate 310 to penetrate the word lines 330, the string selection lines, and the ground selection line. The channel structure CH may include a data storage layer, a channel layer, and a filling insulation layer. The channel layer may be electrically connected to a first metal line 350c and a second metal line 360c in the bit line bonding region BLBA. For example, the second metal line 360c may be a bit line and may be connected to the channel structure CH through the first metal line 350c. The bit line 360c may extend in a first direction (e.g., a Y-axis direction) parallel to the top surface of the second substrate 310.

According to some example embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 310 to penetrate the common source line 320 and lower word lines 331 and 332. The lower channel LCH may include a data storage layer, a channel layer, and a filling insulation layer and may be connected to the upper channel UCH. The upper channel UCH may penetrate upper word lines 333 to 338. The upper channel UCH may include a data storage layer, a channel layer, and a filling insulation layer, and the channel layer of the upper channel UCH may be electrically connected to the first metal line 350c and the second metal line 360c. As a length of a channel increases, due to characteristics of manufacturing processes, it may be difficult to form a channel having a substantially uniform width. The memory device 500 according to some example embodiments may include a channel having improved width uniformity due to the lower channel LCH and the upper channel UCH, which are formed by the processes performed sequentially.

In the case in which the channel structure CH includes the lower channel LCH and the upper channel UCH as illustrated in the region ‘A2’, a word line located near to a boundary between the lower channel LCH and the upper channel UCH may be a dummy word line. For example, the word lines 332 and 333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

In addition, the number of lower word lines (e.g., 331 and 332) penetrated by the lower channel LCH is less than the number of upper word lines (e.g., 333 to 338) penetrated by the upper channel UCH in the region ‘A2’. However, example embodiments are not limited thereto. According to some example embodiments, the number of lower word lines penetrated by the lower channel LCH may be equal to or more than the number of upper word lines penetrated by the upper channel UCH. In addition, structural features and connection relation of the channel structure CH disposed in the second cell region CELL2 may be substantially the same or substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 10, the first through-electrode THV1 may penetrate the common source line 320 and the plurality of word lines 330. According to some example embodiments, the first through-electrode THV1 may further penetrate the second substrate 310. The first through-electrode THV1 may include a conductive material. Alternatively, the first through-electrode THV1 may include a conductive material surrounded by an insulating material. The second through-electrode THV2 may have the same or substantially the same shape and structure as the first through-electrode THV1.

According to some example embodiments, the first through-electrode THV1 and the second through-electrode THV2 may be electrically connected to each other through a first through-metal pattern 372d and a second through-metal pattern 472d. The first through-metal pattern 372d may be formed at a bottom end of the first upper chip including the first cell region CELL1, and the second through-metal pattern 472d may be formed at a top end of the second upper chip including the second cell region CELL2. The first through-electrode THV1 may be electrically connected to the first metal line 350c and the second metal line 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected to each other by the bonding method.

In addition, in the bit line bonding region BLBA, an upper metal pattern 252 may be formed in an uppermost metal layer of the peripheral circuit region PERI, and an upper metal pattern 392 having the same or substantially the same shape as the upper metal pattern 252 may be formed in an uppermost metal layer of the first cell region CELL1. The upper metal pattern 392 of the first cell region CELL1 and the upper metal pattern 252 of the peripheral circuit region PERI may be electrically connected to each other by the bonding method. In the bit line bonding region BLBA, the bit line 360c may be electrically connected to a page buffer included in the peripheral circuit region PERI. For example, some of the circuit elements 220c of the peripheral circuit region PERI may constitute the page buffer, and the bit line 360c may be electrically connected to the circuit elements 220c constituting the page buffer through an upper bonding metal pattern 370c of the first cell region CELL1 and an upper bonding metal pattern 270c of the peripheral circuit region PERI.

Referring again to FIG. 10, in the word line bonding region WLBA, the word lines 330 of the first cell region CELL1 may extend in a second direction (e.g., an X-axis direction) parallel to the top surface of the second substrate 310 and may be connected to a plurality of cell contact plugs 340 (341 to 347). First metal lines 350b and second metal lines 360b may be sequentially connected onto the cell contact plugs 340 connected to the word lines 330. In the word line bonding region WLBA, the cell contact plugs 340 may be connected to the peripheral circuit region PERI through upper bonding metal patterns 370b of the first cell region CELL1 and upper bonding metal patterns 270b of the peripheral circuit region PERI.

The cell contact plugs 340 may be electrically connected to a row decoder included in the peripheral circuit region PERI. For example, some of the circuit elements 220b of the peripheral circuit region PERI may constitute the row decoder, and the cell contact plugs 340 may be electrically connected to the circuit elements 220b constituting the row decoder through the upper bonding metal patterns 370b of the first cell region CELL1 and the upper bonding metal patterns 270b of the peripheral circuit region PERI. According to some example embodiments, an operating voltage of the circuit elements 220b constituting the row decoder may be different from an operating voltage of the circuit elements 220c constituting the page buffer. For example, the operating voltage of the circuit elements 220c constituting the page buffer may be greater than the operating voltage of the circuit elements 220b constituting the row decoder.

Likewise, in the word line bonding region WLBA, the word lines 430 of the second cell region CELL2 may extend in the second direction (e.g., the X-axis direction) parallel to the top surface of the third substrate 410 and may be connected to a plurality of cell contact plugs 440 (441 to 447). The cell contact plugs 440 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 370b may be formed in the first cell region CELL1, and the upper bonding metal patterns 270b may be formed in the peripheral circuit region PERI. The upper bonding metal patterns 370b of the first cell region CELL1 and the upper bonding metal patterns 270b of the peripheral circuit region PERI may be electrically connected to each other by the bonding method. The upper bonding metal patterns 370b and the upper bonding metal patterns 270b may be formed of, e.g., aluminum, copper, or tungsten.

In the external pad bonding region PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by the bonding method in the external pad bonding region PA. Likewise, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by the bonding method.

Common source line contact plugs 380 and 480 may be disposed in the external pad bonding region PA. The common source line contact plugs 380 and 480 may be formed of a conductive material such as a metal, a metal compound, and/or doped polysilicon. The common source line contact plug 380 of the first cell region CELL1 may be electrically connected to the common source line 320, and the common source line contact plug 480 of the second cell region CELL2 may be electrically connected to the common source line 420. A first metal line 350a and a second metal line 360a may be sequentially stacked on the common source line contact plug 380 of the first cell region CELL1, and a first metal line 450a and a second metal line 460a may be sequentially stacked on the common source line contact plug 480 of the second cell region CELL2.

Input/output pads 205, 405 and 406 may be disposed in the external pad bonding region PA. Referring to FIG. 10, a lower insulating layer 201 may cover a bottom surface of the first substrate 210, and a first input/output pad 205 may be formed on the lower insulating layer 201. The first input/output pad 205 may be connected to at least one of a plurality of the circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 to electrically isolate the first input/output contact plug 203 from the first substrate 210.

An upper insulating layer 401 covering a top surface of the third substrate 410 may be formed on the third substrate 410. A second input/output pad 405 and/or a third input/output pad 406 may be disposed on the upper insulating layer 401. The second input/output pad 405 may be connected to at least one of the plurality of circuit elements 220a disposed in the peripheral circuit region PERI through second input/output contact plugs 403 and 303, and the third input/output pad 406 may be connected to at least one of the plurality of circuit elements 220a disposed in the peripheral circuit region PERI through third input/output contact plugs 404 and 304.

According to some example embodiments, the third substrate 410 may not be disposed in a region in which the input/output contact plug is disposed. For example, as illustrated in a region ‘B’, the third input/output contact plug 404 may be separated from the third substrate 410 in a direction parallel to the top surface of the third substrate 410 and may penetrate an interlayer insulating layer 415 of the second cell region CELL2 so as to be connected to the third input/output pad 406. In this case, the third input/output contact plug 404 may be formed by at least one of various processes.

According to some example embodiments, as illustrated in a region ‘B1’, the third input/output contact plug 404 may extend in a third direction (e.g., the Z-axis direction), and a diameter of the third input/output contact plug 404 may become progressively greater toward the upper insulating layer 401. In other words, a diameter of the channel structure CH described in the region ‘A1’ may become progressively less toward the upper insulating layer 401, but the diameter of the third input/output contact plug 404 may become progressively greater toward the upper insulating layer 401. For example, the third input/output contact plug 404 may be formed after the second cell region CELL2 and the first cell region CELL1 are bonded to each other by the bonding method.

According to some example embodiments, as illustrated in a region ‘B2’, the third input/output contact plug 404 may extend in the third direction (e.g., the Z-axis direction), and a diameter of the third input/output contact plug 404 may become progressively less toward the upper insulating layer 401. In other words, like the channel structure CH, the diameter of the third input/output contact plug 404 may become progressively less toward the upper insulating layer 401. For example, the third input/output contact plug 404 may be formed together with the cell contact plugs 440 before the second cell region CELL2 and the first cell region CELL1 are bonded to each other.

According to some example embodiments, the input/output contact plug may overlap with the third substrate 410. For example, as illustrated in a region ‘C’, the second input/output contact plug 403 may penetrate the interlayer insulating layer 415 of the second cell region CELL2 in the third direction (e.g., the Z-axis direction) and may be electrically connected to the second input/output pad 405 through the third substrate 410. In this case, a connection structure of the second input/output contact plug 403 and the second input/output pad 405 may be realized by various methods.

According to some example embodiments, as illustrated in a region ‘C1’, an opening 408 may be formed to penetrate the third substrate 410, and the second input/output contact plug 403 may be connected directly to the second input/output pad 405 through the opening 408 formed in the third substrate 410. In this case, as illustrated in the region ‘C1’, a diameter of the second input/output contact plug 403 may become progressively greater toward the second input/output pad 405. However, example embodiments are not limited thereto, and according to some example embodiments, the diameter of the second input/output contact plug 403 may become progressively less toward the second input/output pad 405.

According to some example embodiments, as illustrated in a region ‘C2’, the opening 408 penetrating the third substrate 410 may be formed, and a contact 407 may be formed in the opening 408. An end of the contact 407 may be connected to the second input/output pad 405, and another end of the contact 407 may be connected to the second input/output contact plug 403. Thus, the second input/output contact plug 403 may be electrically connected to the second input/output pad 405 through the contact 407 in the opening 408. In this case, as illustrated in the region ‘C2’, a diameter of the contact 407 may become progressively greater toward the second input/output pad 405, and a diameter of the second input/output contact plug 403 may become progressively less toward the second input/output pad 405. For example, the second input/output contact plug 403 may be formed together with the cell contact plugs 440 before the second cell region CELL2 and the first cell region CELL1 are bonded to each other, and the contact 407 may be formed after the second cell region CELL2 and the first cell region CELL1 are bonded to each other.

According to some example embodiments illustrated in a region ‘C3’, a stopper 409 may further be formed on a bottom end of the opening 408 of the third substrate 410, as compared with the embodiments of the region ‘C2’. The stopper 409 may be a metal line formed in the same or substantially the same layer as the common source line 420. Alternatively, the stopper 409 may be a metal line formed in the same or substantially the same layer as at least one of the word lines 430. The second input/output contact plug 403 may be electrically connected to the second input/output pad 405 through the contact 407 and the stopper 409.

Like the second and third input/output contact plugs 403 and 404 of the second cell region CELL2, a diameter of each of the second and third input/output contact plugs 303 and 304 of the first cell region CELL1 may become progressively less toward the lower metal pattern 371e or may become progressively greater toward the lower metal pattern 371e.

In addition, according to some example embodiments, a slit 411 may be formed in the third substrate 410. For example, the slit 411 may be formed at a certain position of the external pad bonding region PA. For example, as illustrated in a region ‘D’, the slit 411 may be located between the second input/output pad 405 and the cell contact plugs 440 when viewed in a plan view. Alternatively, the second input/output pad 405 may be located between the slit 411 and the cell contact plugs 440 when viewed in a plan view.

According to some example embodiments, as illustrated in a region ‘D1’, the slit 411 may be formed to penetrate the third substrate 410. For example, the slit 411 may be used to prevent or reduce the third substrate 410 from being finely cracked when the opening 408 is formed. However, example embodiments are not limited thereto, and according to some example embodiments, the slit 411 may be formed to have a depth ranging from about 60% to about 70% of a thickness of the third substrate 410.

According to some example embodiments, as illustrated in a region ‘D2’, a conductive material 412 may be formed in the slit 411. For example, the conductive material 412 may be used to discharge a leakage current occurring in driving of the circuit elements in the external pad bonding region PA to the outside. In this case, the conductive material 412 may be connected to an external ground line.

According to some example embodiments, as illustrated in a region ‘D3’, an insulating material 413 may be formed in the slit 411. For example, the insulating material 413 may be used to electrically isolate the second input/output pad 405 and the second input/output contact plug 403 disposed in the external pad bonding region PA from the word line bonding region WLBA. Since the insulating material 413 is formed in the slit 411, it is possible to prevent or reduce a voltage provided through the second input/output pad 405 from affecting a metal layer disposed on the third substrate 410 in the word line bonding region WLBA.

In addition, according to some example embodiments, the first to third input/output pads 205, 405 and 406 may be selectively formed. For example, the memory device 500 may be realized to include only the first input/output pad 205 disposed on the first substrate 210, to include only the second input/output pad 405 disposed on the third substrate 410, or to include only the third input/output pad 406 disposed on the upper insulating layer 401.

According to some example embodiments, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the bonding process of the peripheral circuit region PERI and the first cell region CELL1, and then, an insulating layer covering a top surface of the common source line 320 or a conductive layer for connection may be formed. Likewise, the third substrate 410 of the second cell region CELL2 may be removed before or after the bonding process of the first cell region CELL1 and the second cell region CELL2, and then, the upper insulating layer 401 covering a top surface of the common source line 420 or a conductive layer for connection may be formed.

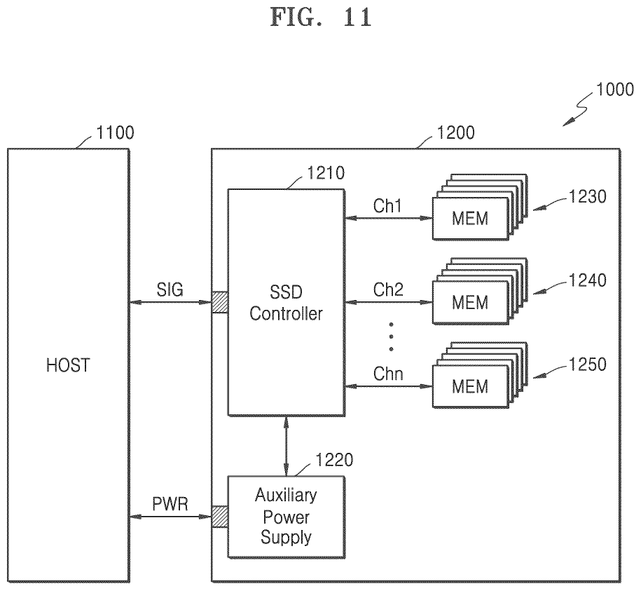

FIG. 11 is a block diagram of an example in which a memory device is implemented in a solid-state drive (SSD) system 1000, according to some example embodiments.

Referring to FIG. 11, the SSD system 1000 may include a host 1100 and an SSD 1200. The SSD 1200 may exchange a signal with the host 1100 through a signal connector and receive a power supply through a power connector. The SSD 1200 may include an SSD controller 1210, an auxiliary power device 1220, and memory devices 1230, 1240, and 1250. The memory devices 1230, 1240, and 1250 may be vertically stacked NAND flash memory devices. Here, the SSD 1200 may be implemented by using the embodiments described above with reference to FIGS. 1 through 10.

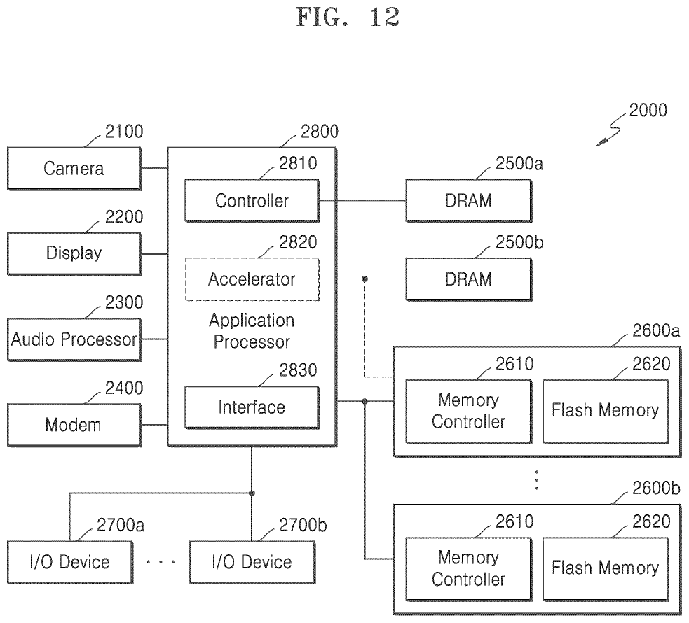

FIG. 12 is a block diagram of a system 2000 of an electronic device including a memory device according to some example embodiments.

Referring to FIG. 11, the system 2000 may include a camera 2100, a display 2200, an audio processor 2300, a modem 2400, dynamic random-access memories (DRAMs) 2500a and 2500b, flash memories 2600a and 2600b, input/output (I/O) devices 2700a and 2700b, and an application processor (AP) 2800. The system 2000 may be implemented by a laptop computer, a mobile terminal, a smart phone, a table personal computer (PC), a wearable device, a health care device, or an Internet of Things (IoT) device. Also, the system 2000 may be implemented by a server or a PC.

The camera 2100 may capture a still image or a video, store the captured image/video data, or transmit the captured image/video data to the display 2200, according to control by a user. The audio processor 2300 may process audio data included in the contents of the flash memories 2600a and 2600b or networks. The modem 2400 may modulate and transmit a signal for transmission and reception of wired/wireless data, and a receiving end may demodulate the signal to restore the original signal. The I/O devices 2700a and 2700b may include devices for providing a digital input and/or output function, such as a universal serial bus (USB), a storage, a digital camera, a secure digital (SD) card, a digital versatile disc (DVD), a network adapter, a touch screen, etc.

The AP 2800 may control general operations of the system 2000. The AP 2800 may include a control block 2810, an accelerator block or an accelerator chip 2820, and an interface block 2830. The AP 2800 may control the display 2200 to display a portion of the contents stored in the flash memories 2600a and 2600b. When a user input is received through the I/O devices 2700a and 2700b, the AP 2800 may perform a control operation corresponding to the user input. The AP 2800 may include an accelerator block, which is an exclusive circuit for artificial intelligence (AI) data calculation, or an accelerator chip 2820 may be separately provided from the AP 2800. The DRAM 2500b may be additionally mounted in the accelerator block or the accelerator chip 2820. The accelerator may be a functional block specialized in a specific function of the AP 2800 and may include a GPU, which is a functional block specialized in graphics data processing, a neural processing unit (NPU), which is a block specialized in AI calculations and inference, and a data processing unit (DPU), which is a block specialized in data transmission.

The system 2000 may include the plurality of DRAMs 2500a and 2500b. The AP 2800 may control the DRAMs 2500a and 2500b according to a command and an MRS complying with the JEDEC standards or may perform communication by setting a DRAM interface regulation to use a business-exclusive function related to low voltage/high speed/reliability and a cyclic redundancy check (CRC)/error correction code (ECC) function. For example, the AP 2800 may communicate with the DRAM 2500a by using an interface according to the JEDEC standards, such as LPDDR4, LPDDR5, etc., and may communicate with the DRAM 2500b by setting a new DRAM interface regulation to control the DRAM 2500b for the accelerator that has a greater band width than the DRAM 2500a.

FIG. 12 illustrates only the DRAMs 2500a and 2500b. However, the disclosure is not limited thereto, and any one of the memories, such as phase-change random access memory (PRAM), static random-access memory (SRAM), magneto-resistive random access memory (MRAM), resistive random access memory (RRAM), ferroelectric random access memory (FRAM), or hybrid random access memory (RAM), that satisfies conditions about a bandwidth, a response rate, and a voltage with respect to the AP 2800 or the accelerator chip 2820, may be used. The DRAMs 2500a and 2500b may have a relatively less latency and a relatively less bandwidth than the I/O devices 2700a and 2700b or the flash memories 2600a and 2600b. The DRAMs 2500a and 2500b may be initialized at a power on time point of the system 2000, and loaded with an operating system and application data, the DRAMs 2500a and 2500b may be used as a temporary storage of the operating system and the application data or as an execution space of various software codes.

In the DRAMs 2500a and 2500b, the four fundamental arithmetic operations of addition/subtraction/multiplication/di-vision, a vector operation, an address operation, or a fast Fourier transform (FET) operation may be performed. Also, in the DRAMs 2500a and 2500b, a function for inference may be performed. Here, the inference may be performed by a deep learning algorithm using an artificial neural network. The deep learning algorithm may include a training operation in which a model is trained by using various data and an inference operation in which the trained model recognizes data. According to some example embodiments, an image captured by a user by using the camera 2100 may be signal processed and stored in the DRAM 2500b, and the accelerator block or the accelerator chip 2820 may perform AI data calculation for recognizing data by using data stored in the DRAM 2500b and the function for inference.

The system 2000 may include a plurality of storages or the plurality of flash memories 2600a and 2600b having greater capacities than the DRAMs 2500a and 2500b. The accelerator block or the accelerator chip 2820 may perform the training operation and the AI data calculation by using the flash memories 2600a and 2600b. According to some example embodiments, the flash memories 2600a and 2600b may include a memory controller 2610 and a flash memory device 2620 and may use an operation device provided in the memory controller 2610 to perform, with relatively increased efficiency, the training operation and the inference AI data calculation performed by the AP 2800 and/or the accelerator chip 2820. The flash memories 2600a and 2600b may store a photograph captured by the camera 2100 or store data transmitted from a data network. For example, augmented reality (AR)/virtual reality (VR), high definition (HD), or ultra-high definition (UHD) contents may be stored.

The components of the system 2000 may include the semiconductor devices and/or the memory devices described with reference to FIGS. 1 to 10. The semiconductor devices and/or the memory devices may include a crack prevention structure between a chip edge region and first and second chipping detection circuits, and the first and second chipping detection circuits may have the same or substantially the same shapes, in which contacts and lines are stacked as multiple layers. Each of the first and second chipping detection circuits may include a line structure, an input buffer and an output buffer connected to the line structure, and may detect cracks of the semiconductor devices. A control logic circuit of the semiconductor devices and/or the memory devices may float the input buffers of the first and second chipping detection circuits and may use the line structures of the first and second chipping detection circuits as a power decoupling capacitor. The control logic circuit may provide a first power voltage to the line structure of the first chipping detection circuit by using a first power switch and may provide a second power voltage to the line structure of the second chipping detection circuit by using a second power switch. The control logic circuit may isolate the line structure of the first chipping detection circuit into a first line and a second line by using a first isolation switch and may isolate the line structure of the second chipping detection circuit into a third line and a fourth line by using a second isolation switch. The control logic circuit may provide a first power voltage to the first line by using a first power switch, a second power voltage to the second line by using a second power switch, a third power voltage to the third line by using a third power switch, and a fourth power voltage to the fourth line by using a fourth power switch. The first power switch providing the first power voltage and the second power switch providing the second power voltage may be connected to the line structure of the first chipping detection circuit, the third power switch providing the third power voltage may be provided to the line structure of the second chipping detection circuit, and the control logic circuit may provide, to the line structure of the first chipping detection circuit, a selected power voltage from the first and second power voltages by using one of the first and second power switches and may provide, to the line structure of the second chipping detection circuit, the third power voltage by using the third power switch. According to the inventive concepts, a semiconductor device having a chip with a decreased size may provide a plurality of power decoupling capacitors by using chipping detection circuits, and thus, may have improved reliability, performance, and lifespan with decreased noise effects caused by voltage fluctuation.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to example embodiments thereof, it will be understood that various changes in form and details may be made therein without departing from the spirit and scope of the following claims.

What is claimed is:

1. A semiconductor device comprising:
a first chipping detection circuit and a second chipping detection circuit which are each
configured to detect cracks of the semiconductor device,
adjacent to each other in a chip edge region of the semiconductor device,
have a same shape, in which contacts and lines are stacked as multiple layers, and
comprises
a line structure,
an input buffer, and
an output buffer connected to the line structure, the line structure comprising a line connected from a first conductive layer to a second conductive layer of the semiconductor device; and
a control logic circuit configured to
float the input buffer of the first chipping detection circuit by using a first switch,
float the input buffer of the second chipping detection circuit by using a second switch,
provide a first power voltage to the line structure of the first chipping detection circuit by using a first power switch, and
provide a second power voltage to the line structure of the second chipping detection circuit by using a second power switch.

2. The semiconductor device of claim 1, wherein the semiconductor device comprises a memory device, and the memory device comprises:
a first semiconductor layer having memory cell arrays on a surface of the first semiconductor layer; and
a second semiconductor layer below the first semiconductor layer, the second semiconductor layer vertically overlapping the first semiconductor layer, and the second semiconductor layer having the control logic circuit on a surface of the second semiconductor layer.

3. The semiconductor device of claim 2, wherein
the first conductive layer is an uppermost conductive layer of the first semiconductor layer,
the second conductive layer is a lowermost conductive layer of the second semiconductor layer, and
the lowermost conductive layer of the second semiconductor layer is on a same level as gate lines of transistors of the control logic circuit of the second semiconductor layer.

4. The semiconductor device of claim 1, wherein
the line structure of the first chipping detection circuit is connected to the first power switch in a plural number, and
the line structure of the second chipping detection circuit is connected to the second power switch in a plural number.

5. The semiconductor device of claim 1, wherein the control logic circuit is configured to control
a level of the first power voltage to be one of internal power voltage levels of the semiconductor device, and
a level of the second power voltage to be a ground voltage level of the semiconductor device.

6. The semiconductor device of claim 1, further comprising a dummy capacitor pattern configured to be connected to the line structures of the first and second chipping detection circuits.

7. The semiconductor device of claim 1, further comprising a crack prevention structure between the first and second chipping detection circuits and the chip edge region of the semiconductor device.

8. A semiconductor device comprising:
a first chipping detection circuit and a second chipping detection circuit which are each
configured to detect cracks of the semiconductor device,
adjacent to each other in a chip edge region of the semiconductor device,
have a same shape as each other, in which contacts and lines are stacked as multiple layers, and
comprise
a line structure,
an input buffer, and
an output buffer connected to the line structure, the line structure comprising a line connected from a plurality of conductive layers of the semiconductor device to a lowermost conductive layer of the semiconductor device; and
a control logic circuit configured to
float the input buffer of the first chipping detection circuit by using a first switch;
float the input buffer of the second chipping detection circuit by using a second switch;
isolate the line structure of the first chipping detection circuit into a first line and a second line by using a first isolation switch; and
isolate the line structure of the second chipping detection circuit into a third line and a fourth line by using a second isolation switch,
the control logic circuit being further configured to:
provide a first power voltage to the first line by using a first power switch;
provide a second power voltage to the second line by using a second power switch;
provide a third power voltage to the third line by using a third power switch; and
provide a fourth power voltage to the fourth line by using a fourth power switch.

9. The semiconductor device of claim 8, wherein the semiconductor device comprises a memory device, and the memory device comprises:
a first semiconductor layer having a memory cell on a surface of the first semiconductor layer; and
a second semiconductor layer below the first semiconductor layer, the second semiconductor layer vertically overlapping the first semiconductor layer and having the control logic circuit on a surface of the second semiconductor layer.

10. The semiconductor device of claim 9, wherein
the first and third lines are uppermost conductive layers of the first semiconductor layer,
the second and fourth lines are conductive layers which are not the uppermost conductive layers from among conductive layers of the first semiconductor layer, and
the lowermost conductive layer is on a same level as gate lines of transistors of the control logic circuit.

11. The semiconductor device of claim 8, wherein
the semiconductor device is configured to be driven by a plurality of internal power voltage levels, and
the control logic circuit is configured to
drive a level of the first power voltage of the first line is a first internal power voltage level from among the plurality of internal power voltage levels,
drive a level of the second power voltage of the second line is a second internal power voltage level from among the plurality of internal power voltage levels, and
drive levels of the third and fourth power voltages of the third and fourth lines are a ground voltage level of the semiconductor device.

12. The semiconductor device of claim 8, wherein
the first line is connected to the first power switch in a plural number,
the second line is connected to the second power switch in a plural number,
the third line is connected to the third power switch in a plural number, and
the fourth line is connected to the fourth power switch in a plural number.

13. The semiconductor device of claim 8, further comprising a crack prevention structure between the first and second chipping detection circuits and the chip edge region of the semiconductor device.

14. A semiconductor device comprising:
a first chipping detection circuit and a second chipping detection circuit which are each
configured to detect cracks of the semiconductor device,
adjacent to each other in a chip edge region of the semiconductor device,
have a same shape as each other, and
comprise
a line structure,
an input buffer, and
an output buffer connected to the line structure, the line structure comprising a line connected from a plurality of conductive layers of the semiconductor device to a lowermost conductive layer of the semiconductor device; and
a control logic circuit configured to
float the input buffer of the first chipping detection circuit by using a first switch and
float the input buffer of the second chipping detection circuit by using a second switch,
the control logic circuit further configured to
control a first power switch to provide a first power voltage,
control a second power switch to provide a second power voltage, and
control a third power switch to provide a third power voltage,
the first and second power switches being connected to the line structure of the first chipping detection circuit, and
the third power switch being connected to the line structure of the second chipping detection circuit.

15. The semiconductor device of claim 14, wherein the control logic circuit is further configured to
provide a selected power voltage from the first and second power voltages to the line structure of the first chipping detection circuit by using one of the first and second power switches and
provide the third power voltage to the line structure of the second chipping detection circuit by using the third power switch.

16. The semiconductor device of claim 14, wherein the semiconductor device comprises a memory device, and the memory device comprises:
a first semiconductor layer having memory cell arrays on a surface of the first semiconductor layer; and
a second semiconductor layer below the first semiconductor layer, the second semiconductor layer vertically overlapping the first semiconductor layer, and the second semiconductor layer having the control logic circuit on a surface of the second semiconductor layer.

17. The semiconductor device of claim 16, wherein
a first conductive layer from among the plurality of conductive layers is a line of the first power voltage,
a second conductive layer from among the plurality of conductive layers is a line of the second power voltage, and
a third conductive layer from among the plurality of conductive layers is a line of the third power voltage.

18. The semiconductor device of claim 17, wherein
the first conductive layer is a first conductive layer of the first semiconductor layer,
the second conductive layer is a second conductive layer of the first semiconductor layer,
the third conductive layer is a third conductive layer of the first semiconductor layer, and
the lowermost conductive layer is on a same level as gate lines of transistors of the control logic circuit of the second semiconductor layer.

19. The semiconductor device of claim 14, wherein
the line structure of the first chipping detection circuit is connected to the first power switch in a plural number, and
the line structure of the second chipping detection circuit is connected to the second power switch in a plural number.

20. The semiconductor device of claim 14, further comprising a crack prevention structure between the first and second chipping detection circuits and the chip edge region of the semiconductor device.
